(19) United States
(12) Patent Application Publication
(10) Pub. No.: US 2025/0169154 A1
(43) Pub. Date: May 22, 2025

(54) SEMICONDUCTOR DEVICE AND METHOD FOR MANUFACTURING THE SAME

(71) Applicant: SK hynix Inc., Gyeonggi-do (KR)

(72) Inventors: Kwan Woo DO, Gyeonggi-do (KR); Hyung Keun KIM, Gyeonggi-do (KR); Ye Cheon CHO, Gyeonggi-do (KR); Jae Sang LEE, Gyeonggi-do (KR)

(21) Appl. No.: 18/928,190

(22) Filed: Oct. 28, 2024

(30) Foreign Application Priority Data
Nov. 20, 2023 (KR) 10-2023-0161546

(51) Int. Cl. H01L 29/49; H01L 29/423

(52) U.S. Cl. CPC H10D 64/667; H10D 64/513

(57) ABSTRACT

A semiconductor device includes a trench formed in a substrate, a gate insulation layer formed to contact a bottom surface and sidewall surfaces of the trench, a first electrode layer formed to contact the gate insulation layer, the first electrode layer comprising titanium, a second electrode layer formed to contact the first electrode layer, the second electrode layer comprising molybdenum and titanium, and a third electrode layer formed to contact the second electrode layer.

### CROSS-REFERENCE TO RELATED APPLICATION

This patent application claims the priority and benefits of Korean patent application No. 10-2023-0161546, filed on Nov. 20, 2023, the disclosure of which is incorporated herein by reference in its entirety as part of the disclosure of this patent application.

### TECHNICAL FIELD

The embodiments of the present disclosure generally relate to a semiconductor device and a method for manufacturing the same, and more particularly to a semiconductor device including a molybdenum (Mo) gate electrode, and a method for manufacturing the same.

### BACKGROUND

As the degree of integration of semiconductor devices increases, the difficulty in designing integrated circuits (ICs) is increasing exponentially.

During development of semiconductor devices, the number of devices included per unit chip area is rapidly increasing while the size of each device is being gradually reduced, and this high degree of integration in semiconductor devices results in increase in the complexity of integrated circuit (IC) processing and IC fabrication.

In particular, as the semiconductor device becomes more highly integrated, the width of a gate electrode included in the semiconductor device decreases and resistance of the gate electrode rapidly increases, resulting in defects or deterioration of characteristics of the semiconductor device.

Therefore, as the resistance of the gate electrode is required to be reduced, attempts to use low-resistance materials such as molybdenum (Mo) for the gate electrode are rapidly increasing.

However, due to the relatively high crystallinity characteristic of molybdenum (Mo), peeling or deformation of the gate electrode made of molybdenum (Mo) may occur. Also, because of the relatively high work function characteristic of molybdenum (Mo), the gate electrode made of molybdenum may be disadvantageous compared to other materials (for example, titanium nitride) in terms of controlling a threshold voltage of the semiconductor device.

Therefore, there is a need for various methods for utilizing molybdenum (Mo) in gate electrodes to manufacture semiconductor devices with better performance while overcoming limitations caused by higher integration of semiconductor devices.

### SUMMARY

In accordance with an embodiment of the present disclosure, a semiconductor device may include a trench formed in a substrate; a gate insulation layer formed to contact a bottom surface and sidewall surfaces of the trench; a first electrode layer formed to contact the gate insulation layer, the first electrode layer comprising titanium; a second electrode layer formed to contact the first electrode layer, the second electrode layer comprising molybdenum and titanium; and a third electrode layer formed to contact the second electrode layer.

In some embodiments, the first electrode layer may further contain nitride that combines with the titanium comprised in the first electrode layer.

In some embodiments, the third electrode layer may contain titanium nitride that combines with the titanium comprised in the third electrode layer.

In some embodiments, the second electrode layer may further contain a molybdenum-titanium alloy and wherein the molybdenum-titanium alloy contains at least some of the molybdenum that the second electrode layer contains and at least some of the titanium that the second electrode layer contains.

In some embodiments, a mass percentage of the titanium included in the second electrode layer may be less than 25%.

In some embodiments, the second electrode layer may further contain silicon.

In some embodiments, a mass percentage of the titanium included in the second electrode layer may be less than 20%, and a mass percentage of the silicon may be less than 20%.

In some embodiments, the second electrode layer may further contain carbon.

In some embodiments, a mass percentage of the titanium included in the second electrode layer may be less than 20%, and a mass percentage of the carbon may be less than 20%.

In some embodiments, the second electrode layer may not contain molybdenum oxide.

In accordance with another embodiment of the present disclosure, a semiconductor device may include a gate insulation layer disposed over a substrate; a first electrode layer formed to contact the gate insulation layer while containing titanium; a second electrode layer formed to contact the first electrode layer while containing molybdenum and the titanium; and a third electrode layer formed to contact the second electrode layer.

In some embodiments, the third electrode layer may contain titanium nitride that combines with the titanium comprised in the third electrode layer.

In some embodiments, the second electrode layer may further contain a molybdenum-titanium alloy and wherein the molybdenum-titanium alloy contains at least some of the molybdenum that the second electrode layer contains and at least some of the titanium that the second electrode layer contains.

In some embodiments, a mass percentage of the titanium included in the second electrode layer may be less than 25%.

In some embodiments, the second electrode layer may further contain silicon.

In some embodiments, a mass percentage of the titanium included in the second electrode layer may be less than 20%, and a mass percentage of the silicon may be less than 20%.

In some embodiments, the second electrode layer may further contain carbon.

In some embodiments, a mass percentage of the titanium included in the second electrode layer may be less than 20%, and a mass percentage of the carbon may be less than 20%.

In accordance with another embodiment of the present disclosure, a method for manufacturing a semiconductor device may include: forming a gate insulation layer configured to contact a substrate; forming a first electrode layer configured to contact the gate insulation layer by repeatedly depositing a reaction gas containing titanium in an in-situ state; forming a second electrode layer configured to contact the first electrode layer by repeatedly depositing a reaction gas containing titanium and a reaction gas containing molybdenum in an in-situ state; and forming a third electrode layer configured to contact the second electrode layer by repeatedly depositing a reaction gas containing titanium in an in-situ state.

In some embodiments, the method for manufacturing the semiconductor device may further include forming a trench in the substrate, wherein the gate insulation layer is formed to contact a bottom surface and sidewall surfaces of the trench.

### BRIEF DESCRIPTION OF THE DRAWINGS

The above and other features and beneficial aspects of the embodiments of the present disclosure will become readily apparent with reference to the following detailed description when considered in conjunction with the accompanying drawings.

FIG. 1 is a perspective view illustrating a portion of a gate electrode of a semiconductor device based on some embodiments of the present disclosure.

FIG. 2 is a perspective view illustrating a portion of a gate electrode of a semiconductor device based on some embodiments of the present disclosure.

FIG. 3 is a flowchart illustrating a method for manufacturing a semiconductor device based on some embodiments of the present disclosure.

### DETAILED DESCRIPTION

Embodiments of the present disclosure provide implementations and examples of a semiconductor device including a molybdenum (Mo) gate electrode and a method for manufacturing the same that may be used in configurations to substantially address one or more technical or engineering issues and to mitigate limitations or disadvantages encountered in some other semiconductor device designs. Some embodiments of the present disclosure relate to a semiconductor device including a gate electrode with controlled resistance characteristics. Some embodiments of the present disclosure relate to a gate electrode including molybdenum (Mo) with improved interface properties. In recognition of the issues above, the semiconductor device based on some embodiments of the present disclosure may have controllable resistance characteristics by adjusting a plurality of material layers included in a gate electrode. The embodiments of the present disclosure provide the semiconductor device in which materials included in a layer containing molybdenum and materials included in layers adjacent to the layer containing molybdenum may be adjusted, resulting in improvement of the interfacial peeling phenomenon of the gate electrode including molybdenum.

Various embodiments of the present disclosure relate to a semiconductor device including a gate electrode with controlled resistance characteristics.

Various embodiments of the present disclosure relate to a gate electrode including molybdenum (Mo) with improved interfacial properties.

It is to be understood that both the foregoing general description and the following detailed description of the embodiments of the present disclosure are illustrative and descriptive and are intended to provide further description of the embodiments as claimed.

Reference will now be made in detail to the embodiments of the present disclosure, examples of which are illustrated in the accompanying drawings. Wherever possible, the same reference numbers will be used throughout the drawings to refer to the same or like parts. While the embodiments of the present disclosure are susceptible to various modifications and alternative forms, specific embodiments thereof are shown by way of example in the drawings. However, this disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized.

The terminology used herein is for the purpose of describing particular embodiments only and is not intended to be limiting of the embodiments. As used herein, the singular forms are intended to include the plural forms as well, unless the context clearly indicates otherwise. It will be further understood that the terms “comprises”, “includes”, “including”, and/or “comprising,” when used in this specification, specify the presence of stated constituent elements, steps, operations, and/or components, but do not preclude the presence or addition of one or more other constituent elements, steps, operations, and/or components thereof. The term “and/or” may include a combination of a plurality of items or any one of a plurality of items.

The drawings may not be necessarily drawn to scale, and in some examples, proportions of at least some of structures in the drawings may be exaggerated to clearly show features of the embodiments. When a multilayer structure having two or more layers is disclosed in the drawings or detailed description, the relative positional relationship or arrangement order of the layers reflects a specific embodiment only and the scope or spirit of the embodiment is not limited thereto, and it should be noted that the relative positional relationship or arrangement order of the layers may also be changed as necessary. In addition, the drawings or detailed descriptions of a multilayer structure may not reflect all layers present in a particular multilayer structure (e.g., one or more additional layers may be present between two illustrated layers). As a specific example, when a first layer in the multilayer structure is referred to as being “on” or “over” a second layer or “on” or “over” a substrate, the first layer may be directly formed on the second layer or the substrate but may also represent a structure where one or more other layers are present between the first layer and the second layer or between the first layer and the substrate.

Hereinafter, a semiconductor device and a method for manufacturing the same based on some embodiments of the present disclosure will be described in detail with reference to the drawings.

A threshold voltage (Vₜ) may refer to a voltage required to create a conductive channel for the operation of a transistor included in a semiconductor device. When a threshold voltage is applied to a gate electrode included in a transistor, a conductive channel may be formed in a substrate included in the transistor.

The threshold voltage may be affected by various factors, for example, a difference in work function between the gate of the transistor and the substrate, the amount of charges in a depletion layer in the substrate, capacitance of a dielectric layer located between the gate and the substrate, a thickness of the dielectric layer, an interface potential (bulk potential), and the like.

The threshold voltage may increase as the work function of the gate electrode increases. When the threshold voltage is high, a high voltage may be required to form a conductive channel within a transistor. Therefore, when the threshold voltage is high, high power may be required to operate the semiconductor device.

On the other hand, when the threshold voltage is low, a conductive channel is formed within the transistor even at a low voltage, which may cause the transistor to operate in an undesirable state.

In order to obtain threshold voltage characteristics required for semiconductor devices, the work function of the gate electrode, the doping concentration of the substrate, the capacitance of the dielectric layer, and the thickness of the dielectric layer should be appropriately adjusted.

However, if the resistance of the gate electrode is high, voltage transfer characteristics of the transistor may deteriorate, so that it is necessary to use a material with an appropriate work function and low resistance characteristics as the gate electrode.

The gate electrode must include a material that can minimize changes in physical properties (e.g., recrystallization, etc.) due to high temperatures, which may be used in a semiconductor manufacturing process.

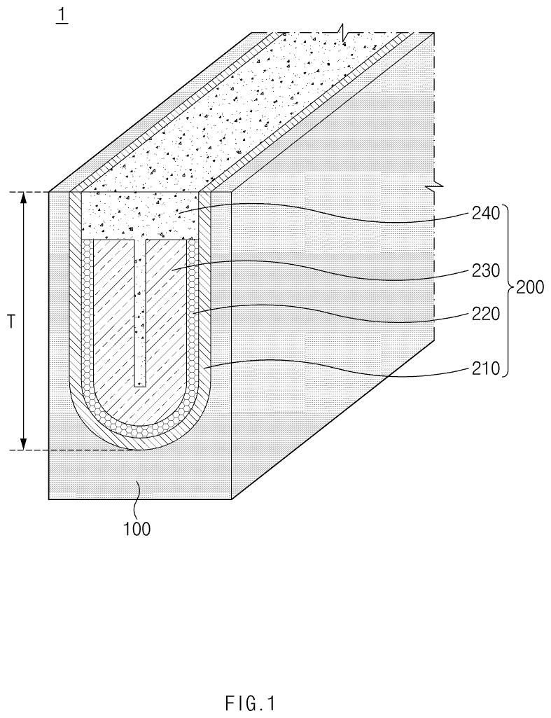

FIG. 1 is a block diagram illustrating a portion of a gate electrode of a semiconductor device based on some embodiments of the present disclosure.

FIG. 1 is a perspective view (1) illustrating a portion of a gate of a semiconductor device based on some embodiments of the present disclosure.

Referring to FIG. 1, the semiconductor device may include a substrate 100 and a trench (T) formed in a substrate 100, and may include a trench gate electrode 200 formed in the trench (T).

The substrate 100 may be a material suitable for semiconductor processing. The substrate 100 may include at least one of a conductive material, a dielectric material (or an insulation material), and a semiconductive material. Various materials may be formed over the substrate 100.

The substrate 100 may include a semiconductor substrate. The substrate 100 may be made of a semiconductor material containing silicon (Si). The substrate 100 may include silicon, monocrystalline silicon, polysilicon, amorphous silicon, silicon germanium, monocrystalline silicon germanium, polycrystalline silicon germanium, carbon doped silicon, combinations thereof, or multilayers thereof.

The substrate 100 may also include other semiconductor materials such as germanium. The substrate 100 may include a group III/V semiconductor substrate, for example, a compound semiconductor substrate such as GaAs.

The substrate 100 may include a monocrystalline silicon substrate, an epitaxial substrate formed through epitaxial growth, or a silicon-on-insulator (SOI) substrate.

For convenience of description, the substrate 100 will hereinafter be described as a semiconductor substrate containing silicon (Si).

In some embodiments, the substrate 100 may include a peripheral circuit region (not shown) at a lower portion thereof.

The peripheral circuit region may include a control circuit for controlling a trench gate electrode 200 included in the semiconductor device. At least one control circuit disposed in the peripheral circuit region may include an N-channel transistor, a P-channel transistor, a CMOS circuit, or a combination thereof.

At least one control circuit included in the peripheral circuit region may be electrically connected to the trench gate electrode 200, and may provide a word line control signal to the trench gate electrode 200.

The trench (T) may be formed, for example, by etching at least a portion of the substrate 100. For example, the trench (T) may be formed in a line shape within the substrate 100.

The trench (T) may be formed, for example, by an etch process in which a mask pattern (not shown) is formed to overlap an upper portion of the substrate 100 and the resultant mask pattern is used as an etch mask.

A plurality of trenches (T) may be formed on the substrate 100 to extend in directions parallel to each other. The plurality of trenches (T) may be spaced apart from each other by a preset distance. In some embodiments, an isolation structure (not shown) physically/electrically isolating the trenches (T) from each other may be disposed between the plurality of trenches (T).

A trench gate electrode 200 may be formed in each of the trenches (T).

When a voltage higher than the threshold voltage is provided to the trench gate electrode 200, a channel may be formed in a portion of the substrate 100 adjacent to the trench gate electrode 200. Charge movement may occur between a source region (not shown) and a drain region (not shown) included in the substrate 100 through the channel.

The trench gate electrode 200 may include a plurality of layers. The trench gate electrode 200 may include a gate insulation layer 210 covering and contacting the bottom surface and sidewall surfaces of the trench (T), a first electrode layer 220 covering and contacting the gate insulation layer 210, a second electrode layer 230 covering and contacting the first electrode layer 220, and a third electrode layer 240 contacting the second electrode layer 230. The uppermost surfaces of the first and second electrode layers 220 and 230 may be at the same level and may leave exposed an uppermost portion of the gate insulation layer 210 that is covered with third electrode layer 240.

The gate insulation layer 210 may include an insulation material such as, for example, silicon oxide or silicon nitride.

The gate insulation layer 210 may be formed, for example, by thermal oxidation, chemical vapor deposition (CVD), or atomic layer deposition (ALD).

In some embodiments, the gate insulation layer 210 may include high-permittivity (high-K) materials. For example, the high-permittivity (high-K) material may refer to materials with a higher dielectric constant than silicon oxide or silicon nitride.

The high-permittivity (high-K) material may include, for example, metal oxides such as hafnium oxide or aluminum oxide.

The concentration of the high-permittivity (high-K) material included in the gate insulation layer 210 may vary according to the threshold voltage characteristics of the semiconductor device.

For example, for reducing a threshold voltage for the semiconductor device, the concentration of the high-permittivity (high-K) material included in the gate insulation layer 210 may be increased. The concentration of the high-permittivity (high-K) material may be adjusted by controlling the degree of diffusion of the high-permittivity (high-K) material into the gate insulation layer 210 through heat treatment.

For obtaining a high threshold voltage for the semiconductor device, the gate insulation layer 210 may not include a high-permittivity (high-K) material.

The first electrode layer 220 may be disposed to contact the gate insulation layer 210. The first electrode layer 220 may include, for example, titanium (Ti).

In some embodiments, the first electrode layer 220 may further include, for example, titanium nitride (TiN) as well as titanium (Ti).

The first electrode layer 220 may be formed to overlap with the bottom surface and sidewall surfaces of the gate insulation layer 210.

In some embodiments, after forming the gate insulation layer 210 in a reaction chamber, the first electrode layer 220 may be formed, for example, through chemical vapor deposition (CVD) or atomic layer deposition (CVD) in the same reaction chamber as the one used to form the gate insulation layer 210. A high vacuum state may be maintained inside the reaction chamber. The first electrode layer 220 may be formed in-situ.

The first electrode layer 220 may be deposited in a reaction chamber maintained in a high vacuum state after the gate insulation layer 210 is formed.

For example, in some embodiments the first electrode layer 220 may be formed through atomic layer deposition (ALD).

The first electrode layer 220 may include, for example, titanium (Ti) deposited using TiCl₄ gas and H₂ gas as reaction gases, or may include, for example, titanium nitride deposited using TiCl₄ gas and NH₃ gas as reaction gases.

Since the first and second electrode layers 220 and 230 may commonly contain titanium (Ti), stress occurring at an interface between electrode layers or in an interface between the electrode layer and the insulation layer due to excessive crystallization of the second electrode layer 230 may be reduced substantially.

The second electrode layer 230 may be disposed to contact the first electrode layer 220. The second electrode layer 230 may include, for example, titanium (Ti) and molybdenum (Mo).

Since the second electrode layer 230 includes molybdenum with low resistivity, the resistivity of the trench gate electrode 200 may be reduced substantially and may improve the semiconductor device characteristics.

The mass percentage of titanium included in the second electrode layer 230 may be less than 25%.

The mass percentage of a substance in the second electrode layer may refer to a mass percentage of the substance to the total mass of the second electrode layer 230. The fact that the mass percentage of titanium included in the second electrode layer 230 is 25% may mean that the mass of titanium represents 25% of the total mass of the second electrode layer 230.

In some embodiments, the second electrode layer 230 may further include silicon or carbon, in addition to the titanium. The mass percentage of silicon (Si) contained in the second electrode layer 230 may be less than 20%. The mass percentage of carbon included in the second electrode layer 230 may be less than 20%.

In some embodiments, titanium and molybdenum included in the second electrode layer 230 may form a molybdenum-titanium alloy.

The molybdenum-titanium alloy may further contain silicon or carbon. The mass percentage of titanium, silicon, or carbon contained in the molybdenum-titanium alloy may be less than 20%.

The work function of the trench gate electrode 200 may be adjusted by adjusting the amount of molybdenum, titanium, silicon, or carbon included in the second electrode layer 230.

The second electrode layer 230 may be formed to overlap with the bottom surface and sidewall surfaces of the first electrode layer 220.

In some embodiments, after forming the first electrode layer 220 in a reaction chamber, the second electrode layer 230 may be formed, for example, through chemical vapor deposition (CVD) or atomic layer deposition (ALD) in the same reaction chamber as the first electrode layer 220. The reaction chamber in which the second electrode layer 230 is formed may be maintained in a high vacuum state. The second electrode layer 230 may be formed in-situ.

The second electrode layer 230 may be deposited in a reaction chamber maintained in a high vacuum state after the first electrode layer 220 is formed.

For example, in some embodiments the second electrode layer 230 may be formed through atomic layer deposition (ALD).

The second electrode layer 230 may include, for example, molybdenum and titanium deposited using MoCl₅ gas, TiCl₄ gas, and H₂ gas as reaction gases.

In some embodiments, the second electrode layer 230 may further include silicon by further using SiH₄ as a reaction gas.

In some embodiments, the second electrode layer 230 may further include carbon by using a hydrocarbon (e.g., CH₄, etc.) as a reaction gas.

Since the second electrode layer 230 may include titanium, excessive crystallization of molybdenum (Mo) due to a high temperature process may be prevented.

When molybdenum is excessively crystallized, the concentration of molybdenum crystals with low physical stability may increase in the second electrode layer 230. In particular, molybdenum crystals can adversely affect the physical stability of the gate electrode by acting as a factor that causes interfacial stress at the interface contacting other materials.

When the concentration of molybdenum crystals included in the second electrode layer 230 increases, interfacial peeling and banding phenomena of the trench gate electrode 200 may occur.

In some embodiments, a first electrode layer 220 containing titanium or titanium nitride may be formed between the second electrode layer 230 containing titanium and molybdenum and the gate insulation layer 210 containing silicon oxide acting as a non-metallic material, so that it is possible to alleviate interfacial stress that may occur between the second electrode layer 230 and the gate insulation layer 210.

In addition, in a situation where the work function of titanium or titanium nitride included in the first electrode layer 220 is 4.3 to 4.5 eV (electron volts) and the work function of molybdenum included in the second electrode layer 230 is 5 eV, the first electrode layer 220 containing titanium or titanium nitride may be formed and the second electrode layer 230 includes titanium, thereby lowering the work function of the trench gate electrode 200 to an appropriate level.

By adjusting the work function of the trench gate electrode 200 to an appropriate level, the threshold voltage of the semiconductor device may decrease, thereby reducing power consumption for operation of the semiconductor device.

In addition, since titanium (Ti) has a different crystal form from molybdenum (Mo), excessive crystallization of molybdenum during a high temperature process may be reduced by the second electrode layer 230 containing titanium.

More specifically, the titanium has an hexagonal crystal form, while the molybdenum has a cubic crystal form. Due to their different crystal forms, the titanium may interfere with the crystallization of molybdenum.

In some embodiments, since the work function of silicon is 4.1 eV and the second electrode layer 230 includes silicon, the work function of the trench gate electrode 200 may be lowered to an appropriate level. In addition, when the second electrode layer 230 includes silicon, excessive crystallization of molybdenum during a high temperature process may be prevented due to non-metallic silicon included in the second electrode layer 230.

In some embodiments, the work function of carbon is 4.8 to 5 eV and the second electrode layer 230 includes carbon, so that the work function of the trench gate electrode 200 may be lowered to an appropriate level. In addition, when the second electrode layer 230 includes carbon, excessive crystallization of molybdenum during a high temperature process may be prevented due to non-metallic carbon.

The thickness of the second electrode layer 230 within the trench gate electrode 200 may be larger than the thickness of the first electrode layer 220. It has been found, that as the area occupied by the second electrode layer 230 within the trench gate electrode 200 increases in size, the effect of reducing resistance of the trench gate electrode 200 due to molybdenum may increase.

The third electrode layer 240 may be disposed to contact the second electrode layer 230. The third electrode layer 240 may include, for example, titanium nitride.

The third electrode layer 240 may be formed to contact the sidewall surfaces of the second electrode layer 230, and may be formed to overlap with uppermost surfaces of the first and second electrode layers 220 and 230.

Since the third electrode layer 240 overlaps with the uppermost surfaces of the first and second electrode layers 220 and 230, the first and second electrode layers 220 and 230 may be prevented from being exposed outside after completing formation of the third electrode layer 240.

As the third electrode layer 240 is formed, oxidation of molybdenum contained in the second electrode layer 230 may be prevented. The second electrode layer 230 and the third electrode layer 240 are formed in situ, and the third electrode layer 240 is formed, so that the second electrode layer 230 may not include, for example, molybdenum oxide.

The third electrode layer 240 may include, for example, titanium nitride with high oxidation resistance. Since the third electrode layer 240 is provided, oxidation of the first and second electrode layers 220 and 230 may be prevented. In particular, oxidation of molybdenum due to oxygen in the atmosphere may be prevented. The third electrode layer 240 may be a capping layer of the first and second electrode layers 220 and 230.

In some embodiments, the third electrode layer 240 may be formed, for example, through chemical vapor deposition (CVD) or atomic layer deposition (ALD) in the same reaction chamber after the second electrode layer 230 is formed. The reaction chamber in which the third electrode layer 240 is formed may be maintained in a high vacuum state. The third electrode layer 240 may be formed in-situ.

The third electrode layer 240 may be deposited in a reaction chamber maintained in a high vacuum state after the second electrode layer 230 is formed.

For example, in some embodiments the third electrode layer 240 is formed through atomic layer deposition (ALD).

The third electrode layer 240 may include, for example, titanium nitride deposited using TiCl₄ gas and NH₃ gas as reaction gases.

The shape of the third electrode layer 240 may vary depending on the deposition shapes of the first and second electrode layers 220 and 230. For example, unlike what is shown in FIG. 1, the area of the third electrode layer 240 formed between the second electrode layers 230 may be omitted. When the second electrode layer 230 is formed tightly inside the trench (T), the third electrode layer 240 may be formed in a planar shape. Each of the first and second electrode layers 220 and 230 may be formed in a flat shape, and may be deposited in a shape that overlaps top surfaces of the first and second electrode layers 220 and 230.

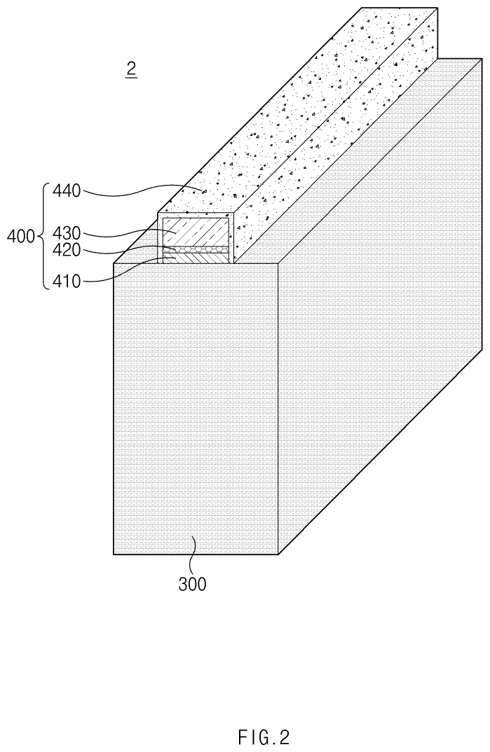

FIG. 2 is a perspective view (2) illustrating a portion of a gate electrode of a semiconductor device based on some embodiments of the present disclosure.

Referring to FIG. 2, the semiconductor device may include a substrate 300 and a planar gate electrode 400 formed on the substrate 300.

The trench gate electrode 200 shown in FIG. 1 and the planar gate electrode 400 shown in FIG. 2 have different shapes, but the gate insulation layer 410, the first electrode layer 420, the second electrode layer 430, and the third electrode layer 440 included in the planar gate electrode 400 of FIG. 2 may correspond to the gate insulation layer 210, the first electrode layer 220, the second electrode layer 230, and the third electrode layer 240 of FIG. 1, and as such redundant description thereof will herein be omitted for brevity.

For example, the substrate 300 will hereinafter be described as a semiconductor substrate containing silicon. As previously described in FIG. 1, the substrate 300 may include a peripheral circuit region at a lower portion thereof. The substrate 300 may also include a control circuit included in the peripheral circuit region which may be electrically connected to the planar gate electrode 400. The control circuit may provide a word line control signal to the planar gate electrode 400.

The planar gate electrode 400 may be formed to overlap with the upper portion of the substrate 300, and may have a line shape extending in one direction.

The planar gate electrode 400 may be formed over the substrate 300 through a deposition process.

When a voltage higher than the threshold voltage is provided to the planar gate electrode 400, a channel may be formed in a portion of the substrate 300 below the planar gate electrode 400. Charge movement may occur between a source region (not shown) and a drain region (not shown) included in the substrate 300 through the channel.

The planar gate electrode 400 may include a plurality of layers.

The planar gate electrode 400 may include a gate insulation layer 410 formed to contact the upper (e.g., uppermost) portion of the substrate 300, a first electrode layer 420 formed to contact the gate insulation layer 410, a second electrode layer 430 formed to contact the first electrode layer 420, and a third electrode layer 440 formed to contact the second electrode layer 430.

The gate insulation layer 410 may include an insulation material such as, for example, silicon oxide or silicon nitride.

The gate insulation layer 410 may be formed, for example, by thermal oxidation, chemical vapor deposition (CVD), or atomic layer deposition (ALD).

The gate insulation layer 410 may include high-permittivity materials with a higher dielectric constant than silicon oxide or silicon nitride.

The first electrode layer 420 may be disposed to cover and contact the gate insulation layer 410. The first electrode layer 420 may include, for example, titanium (Ti).

In some embodiments, the first electrode layer 420 may further include, for example, titanium nitride (TiN) as well as titanium (Ti).

The first electrode layer 420 may be an intermediate layer disposed between the gate insulation layer 410 and the second electrode layer 430, and may mitigate interfacial stress between the two layers. The first electrode layer 420 may be formed, for example, through atomic layer deposition (ALD) in situ.

After the gate insulation layer 410 is formed, the first electrode layer 420 may be deposited over the gate insulation layer 410 in a reaction chamber maintained in a high vacuum state.

The second electrode layer 430 may be disposed to contact the first electrode layer 420. The second electrode layer 430 may be disposed over the first electrode layer 420 to cover the first electrode layer. The second electrode layer 430 may include, for example, titanium (Ti) and molybdenum (Mo).

The mass percentage of titanium included in the second electrode layer 430 may be less than 25%.

In addition, the second electrode layer 430 may further include silicon or carbon. The mass percentage of silicon contained in the second electrode layer 430 may be less than 20%. The mass percentage of carbon included in the second electrode layer 430 may be less than 20%.

In some embodiments, titanium and molybdenum included in the second electrode layer 430 may form a molybdenum-titanium alloy.

In some embodiments, the molybdenum-titanium alloy may further include silicon or carbon. The mass percentage of titanium, silicon, or carbon contained in the molybdenum-titanium alloy may be less than 20%.

Since the amount of molybdenum, titanium, silicon, or carbon included in the second electrode layer 430 is adjusted, the work function of the planar gate electrode 400 may be adjusted to an appropriate level.

The second electrode layer 430 may be formed, for example, through atomic layer deposition (ALD) in situ.

The second electrode layer 430 in the planar gate electrode 400 may have a larger thickness than the first electrode layer 420. It has been found, that as the area occupied by the second electrode layer 430 within the planar gate electrode 400 increases in size, the effect of reducing resistance of the planar gate electrode 400 due to molybdenum may increase.

The third electrode layer 440 may be disposed to contact the second electrode layer 430. The third electrode layer 440 may be disposed over the second electrode layer 430 and may cover the second electrode layer 430.

The third electrode layer 440 may also be disposed to cover and contact the sidewall surfaces of the gate insulation layer 410, the first electrode layer 420, and the second electrode layer 430. The third electrode layer 440 may overlap with the second electrode layer 430. The third electrode layer 440 may include, for example, titanium nitride with high oxidation resistance.

Since the third electrode layer 440 contacts the sidewall surfaces of the first electrode layer 420 and the second electrode layer 430, and overlaps the top surface of the second electrode layer 430, after forming the third electrode layer 440, the first electrode layer 420 and the second electrode layer 430 may be prevented from being exposed outside.

The third electrode layer 440 may prevent oxidation of molybdenum due to oxygen in the atmosphere. Hence, the third electrode layer 440 may serve as a capping layer for the first electrode layer 420 and the second electrode layer 430.

The third electrode layer 440 may be formed, for example, through atomic layer deposition (ALD) in situ.

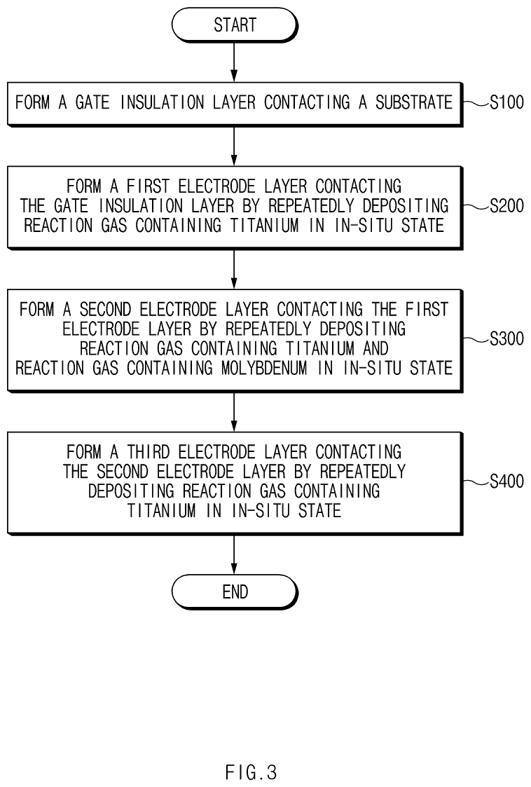

FIG. 3 is a flowchart illustrating a method for manufacturing the semiconductor device based on some embodiments of the present disclosure.

Accordingly, a method for manufacturing the semiconductor device may include forming the gate insulation layer contacting the substrate (S100).

For example, the substrate may include a semiconductor substrate such as a silicon substrate.

In some embodiments, before the gate insulation layer is formed, a trench may be formed, for example, by etching at least a portion of the substrate. When a trench is formed, the gate insulation layer may contact the bottom surface and sidewall surfaces of the trench located inside the substrate.

The gate insulation layer may be formed, for example, by chemical vapor deposition (CVD) or atomic layer deposition (ALD).

For example, the gate insulation layer may include silicon oxide or silicon nitride.

When the gate insulation layer containing silicon oxide is formed through atomic layer deposition (ALD), oxygen (O₂) may be used as a reaction gas and argon (Ar) may be used as a purge gas.

More specifically, in order to deposit the gate insulation layer containing silicon oxide, a substrate may be disposed in a reaction chamber, oxygen serving as a reaction gas may be injected, and the gate insulation layer may be formed using the adsorbed reaction gas. After only one gate insulation layer is formed, excess oxygen gas may be discharged out of the reaction chamber using argon as a purge gas.

A gate insulation layer including a homogeneous silicon oxide layer may be deposited by sequentially performing a process of injecting reaction gas, a process of adsorbing reaction gas, a process of forming the gate insulation layer, and a process of discharging excess gas.

After forming the gate insulation layer, the reaction gas containing titanium may be repeatedly deposited in-situ to form a first electrode layer contacting the gate insulation layer (S200).

The first electrode layer may be deposited in a high vacuum state. While the first electrode layer is deposited, the reaction chamber and the outside may be disconnected.

The first electrode layer may be formed to contact the bottom surface and sidewall surfaces of the gate insulation layer.

The first electrode layer may be formed, for example, by chemical vapor deposition (CVD) or atomic layer deposition (ALD).

For example, the atomic layer deposition (ALD) process for forming the first electrode layer may be performed at 400 to 600° C.

For example, the first electrode layer may include titanium.

When the first electrode layer containing titanium is formed through atomic layer deposition (ALD), TiCl₄ and H₂ may be used as reaction gases and argon (Ar) may be used as a purge gas.

More specifically, TiCl₄ gas serving as the reaction gas may be injected into the substrate on which the gate insulation layer is deposited, and TiCl₄ gas may be adsorbed on the top of the gate insulation layer. The remaining TiCl₄ gas except for the adsorbed TiCl₄ may be discharged outside the reaction chamber using argon (Ar) gas as a purge gas. Thereafter, when H₂ gas is injected into the reaction chamber, the H₂ gas may react with the adsorbed TiCl₄ to form a titanium (Ti) layer. After the titanium (Ti) layer is formed, the remaining H₂ gas may be discharged outside the reaction chamber using argon gas as a purge gas.

The first electrode layer including a homogeneous titanium layer may be deposited by sequentially performing a process of injecting TiCl₄ gas, a process of adsorbing the TiCl₄ gas, a process of discharging the TiCl₄ gas, a process of injecting the H₂ gas, a process of forming the first electrode layer, and a process of discharging the H₂ gas.

When the first electrode layer containing titanium nitride is formed through atomic layer deposition (ALD), TiCl₄ gas and NH₃ gas may be used as reaction gases and argon (Ar) may be used as a purge gas.

The first electrode layer including a homogeneous titanium nitride layer may be deposited by sequentially performing a process of injecting TiCl₄ gas, a process of adsorbing the TiCl₄ gas, a process of discharging the TiCl₄ gas, a process of injecting the NH₃ gas, a process of forming the first electrode layer, and a process of discharging the NH₃ gas.

After forming the first electrode layer, a reaction gas containing titanium and a reaction gas containing molybdenum may be repeatedly deposited in-situ to form a second electrode layer contacting the first electrode layer (S300).

The second electrode layer may be formed to contact the bottom surface and sidewall surfaces of the first electrode layer.

The second electrode layer may be formed, for example, by chemical vapor deposition (CVD) or atomic layer deposition (ALD).

For example, the atomic layer deposition (ALD) process for forming the second electrode layer may be performed at 400 to 600° C.

In some embodiments, the second electrode layer may include a molybdenum-titanium alloy.

When the second electrode layer containing molybdenum and titanium is formed through atomic layer deposition (ALD), MoCl₅, TiCl₄, and H₂ may be used as reaction gases and argon (Ar) may be used as a purge gas.

More specifically, MoCl₅ gas serving as a reaction gas may be injected into the substrate on which the first electrode layer is deposited, and the MoCl₅ gas may be adsorbed on the top of the first electrode layer. The remaining MoCl₅ gas except for the adsorbed MoCl₅ may be discharged outside the reaction chamber using argon gas as a purge gas. Thereafter, when H₂ gas is injected into the reaction chamber, the H₂ gas reacts with the adsorbed MoCl₅ to form a molybdenum layer. After the molybdenum layer is formed, the remaining H₂ gas may be discharged outside the reaction chamber using argon gas as a purge gas.

Afterwards, TiCl₄ gas may be injected into the substrate on which the deposited molybdenum layer is deposited, and TiCl₄ gas may be adsorbed on the top of the molybdenum layer. The remaining TiCl₄ gas, excluding the adsorbed TiCl₄, may be discharged outside the reaction chamber using argon gas as a purge gas. Afterwards, when H₂ gas is injected into the reaction chamber, the H₂ gas may react with the adsorbed TiCl₄ to form a titanium layer. After the titanium layer is formed, the remaining H₂ gas may be discharged outside the reaction chamber using argon gas as a purge gas.

The second electrode layer including a homogeneous molybdenum layer and a titanium layer may be deposited by sequentially performing a process of injecting MoCl₅ gas, a process of adsorbing the MoCl₅ gas, a process of discharging the MoCl₅ gas, a process of injecting the H₂ gas, a process of forming the molybdenum layer, a process of discharging the H₂ gas, a process of injecting TiCl₄ gas, a process of adsorbing the TiCl₄ gas, a process of discharging the TiCl₄ gas, a process of injecting the H₂ gas, a process of forming a titanium layer, and a process of discharging the H₂ gas.

In some embodiments, when the second electrode layer includes molybdenum, titanium, and silicon, MoCl₅, TiCl₄, H₂, and SiH₄ may be used as reaction gases, and argon (Ar) may be used as a purge gas.

When the second electrode layer includes silicon, a process of injecting SiH₄, a process of adsorbing SiH₄, and a process of discharging SiH₄ may be further performed.

A homogeneous molybdenum layer and a titanium layer may be formed by sequentially performing a process of injecting MoCl₅ gas, a process of adsorbing the MoCl₅ gas, a process of discharging the MoCl₅ gas, a process of injecting the H₂ gas, a process of forming the molybdenum layer, a process of discharging the H₂ gas, a process of injecting TiCl₄ gas, a process of adsorbing the TiCl₄ gas, a process of discharging the TiCl₄ gas, a process of injecting the H₂ gas, a process of forming a titanium layer, and a process of discharging the H₂ gas. Subsequently, a process of injecting SiH₄, a process of adsorbing SiH₄, and a process of discharging SiH₄ may be sequentially performed, resulting in formation of the second electrode layer including silicon.

In some embodiments, when the second electrode layer includes molybdenum, titanium and carbon, MoCl₅, TiCl₄, H₂ and hydrocarbon gas (e.g., CH₄ gas) may be used as reaction gases, and argon (Ar) may be used as a purge gas.

When the second electrode layer includes carbon, a process of injecting hydrocarbon gas, a process of adsorbing the hydrocarbon gas, and a process of discharging the hydrocarbon gas may be further performed.

A homogeneous molybdenum layer and a titanium layer may be formed by sequentially performing a process of injecting MoCl₅ gas, a process of adsorbing the MoCl₅ gas, a process of discharging the MoCl₅ gas, a process of injecting the H₂ gas, a process of forming the molybdenum layer, a process of discharging the H₂ gas, a process of injecting TiCl₄ gas, a process of adsorbing the TiCl₄ gas, a process of discharging the TiCl₄ gas, a process of injecting the H₂ gas, a process of forming a titanium layer, and a process of discharging the H₂ gas. Subsequently, a process of injecting hydrocarbon gas, a process of adsorbing the hydrocarbon gas, and a process of discharging the hydrocarbon gas may be sequentially performed, resulting in formation of the second electrode layer including carbon.

In some embodiments, when forming the titanium layer, the second electrode layer may contain nitrogen using NH₃ gas instead of H₂ gas.

A homogeneous molybdenum layer and a titanium nitride layer may be formed by sequentially performing a process of injecting MoCl₅ gas, a process of adsorbing the MoCl₅ gas, a process of discharging the MoCl₅ gas, a process of injecting the H₂ gas, a process of forming the molybdenum layer, a process of discharging the H₂ gas, a process of injecting TiCl₄ gas, a process of adsorbing the TiCl₄ gas, a process of discharging the TiCl₄ gas, a process of injecting the NH₃ gas, a process of forming a titanium nitride layer, and a process of discharging the NH₃ gas, so that the second electrode layer including carbon may contain nitrogen.

After the second electrode layer is formed, the reaction gas containing titanium may be repeatedly deposited in-situ to form a third electrode layer contacting the second electrode layer (S400).

The third electrode layer may be formed in a reaction chamber in a high vacuum state.

The third electrode layer may be formed to contact the bottom surface and sidewall surfaces of the second electrode layer, and may be formed to overlap with the top surfaces of the first electrode layer and the second electrode layer.

The third electrode layer may block the first electrode layer and the second electrode layer from being exposed outside, so that the third electrode layer may prevent oxidation of the first and second electrode layers.

Since the third electrode layer is formed, oxidation of molybdenum contained in the second electrode layer may be prevented.

In the same manner as the process of forming the first electrode layer containing titanium nitride through atomic layer deposition (ALD), the atomic layer deposition (ALD) process for forming the third electrode layer may also be performed at 400 to 600° C.

When the third electrode layer containing titanium nitride is formed through atomic layer deposition (ALD), TiCl₄ and NH₃ may be used as reaction gases and argon (Ar) may be used as a purge gas.

A third electrode layer including a homogeneous titanium nitride layer may be formed, for example, by sequentially performing a process of injecting TiCl₄ gas, a process of adsorbing the TiCl₄ gas, a process of discharging the TiCl₄ gas, a process of injecting the NH₃ gas, a process of forming the first electrode layer, and a process of discharging the NH₃ gas.

As is apparent from the above description, the semiconductor device based on some embodiments of the present disclosure may have controllable resistance characteristics by adjusting a plurality of material layers included in a gate electrode.

In addition, the embodiments of the present disclosure provide the semiconductor device in which materials included in a layer containing molybdenum and materials included in layers adjacent to the layer containing molybdenum may be adjusted, resulting in improvement of the interfacial peeling phenomenon of the gate electrode including molybdenum.

The embodiments of the present disclosure may provide a variety of effects capable of being directly or indirectly recognized.

Those skilled in the art will appreciate that the embodiments of the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and/or enhancements to the disclosed embodiments and other embodiments may be devised based on what is described and/or illustrated in the present disclosure. Furthermore, the embodiments may be combined to form additional embodiments.

What is claimed is:

1. A semiconductor device comprising:
a trench formed in a substrate;
a gate insulation layer formed to contact a bottom surface and sidewall surfaces of the trench;
a first electrode layer formed to contact the gate insulation layer, the first electrode layer comprising titanium;
a second electrode layer formed to contact the first electrode layer, the second electrode layer comprising molybdenum and titanium; and
a third electrode layer formed to contact the second electrode layer.

2. The semiconductor device according to claim 1, wherein
the first electrode layer further contains nitride that combines with the titanium comprised in the first electrode layer.

3. The semiconductor device according to claim 1, wherein
the third electrode layer contains titanium nitride.

4. The semiconductor device according to claim 1, wherein
the second electrode layer further contains a molybdenum-titanium alloy, and
wherein the molybdenum-titanium alloy contains at least some of the molybdenum that the second electrode layer contains and at least some of the titanium that the second electrode layer contains.

5. The semiconductor device according to claim 1, wherein
a mass percentage of the titanium included in the second electrode layer is less than 25%.

6. The semiconductor device according to claim 1, wherein
the second electrode layer further contains silicon.

7. The semiconductor device according to claim 6, wherein
a mass percentage of the titanium included in the second electrode layer is less than 20%; and
a mass percentage of the silicon is less than 20%.

8. The semiconductor device according to claim 1, wherein
the second electrode layer further contains carbon.

9. The semiconductor device according to claim 8, wherein
a mass percentage of the titanium included in the second electrode layer is less than 20%; and
a mass percentage of the carbon is less than 20%.

10. The semiconductor device according to claim 1, wherein
the second electrode layer is formed not to contain molybdenum oxide.

11. A semiconductor device comprising:
a gate insulation layer disposed over a substrate;
a first electrode layer formed to contact the gate insulation layer while containing titanium;
a second electrode layer formed to contact the first electrode layer while containing molybdenum and titanium; and
a third electrode layer formed to contact the second electrode layer.

12. The semiconductor device according to claim 11, wherein
the third electrode layer contains titanium nitride.

13. The semiconductor device according to claim 11, wherein
the second electrode layer further contains a molybdenum-titanium alloy, and
wherein the molybdenum-titanium alloy contains at least some of the molybdenum that the second electrode layer contains and at least some of the titanium that the second electrode layer contains.

14. The semiconductor device according to claim 11, wherein
a mass percentage of the titanium included in the second electrode layer is less than 25%.

15. The semiconductor device according to claim 11, wherein
the second electrode layer further contains silicon.

16. The semiconductor device according to claim 15, wherein
a mass percentage of the titanium included in the second electrode layer is less than 20%; and
a mass percentage of the silicon is less than 20%.

17. The semiconductor device according to claim 11, wherein
the second electrode layer further contains carbon.

18. The semiconductor device according to claim 17, wherein
a mass percentage of the titanium included in the second electrode layer is less than 20%; and
a mass percentage of the carbon is less than 20%.

19. A method for manufacturing a semiconductor device, the method comprising:
forming a gate insulation layer configured to contact a substrate;
forming a first electrode layer configured to contact the gate insulation layer by repeatedly depositing a reaction gas containing titanium in an in-situ state;
forming a second electrode layer configured to contact the first electrode layer by repeatedly depositing a reaction gas containing titanium and a reaction gas containing molybdenum in an in-situ state; and
forming a third electrode layer configured to contact the second electrode layer by repeatedly depositing a reaction gas containing titanium in an in-situ state.

20. The method according to claim 19, further comprising:
forming a trench in the substrate,
wherein
the gate insulation layer is formed to contact a bottom surface and sidewall surfaces of the trench.
